(19) United States
(12) Patent Application Publication
(10) Pub. No.: US 2008/0036483 A1
(43) Pub. Date: Feb. 14, 2008

(54) Probe card for flip chip testing

(75) Inventor: Ming-Cheng Hsu, Hsinchu (TW)

Correspondence Address: BIRCH, STEWART, KOLASCH & BIRCH, LLP, PO BOX 747, 8110 GATEHOUSE RD, STE 500 EAST, FALLS CHURCH, VA, 22040-0747, US

(73) Assignee: TAIWAN SEMICONDUCTOR MANUFACTURING CO., LTD.

(21) Appl. No.: 11/500,454

(22) Filed: Aug. 8, 2006

(51) Int. Cl. G01R 31/28

(52) U.S. Cl. 324/761; 29/825

(57) ABSTRACT

A probe card for testing a flip chip device is provided. In one embodiment, the probe card comprises a printed circuit board having a first surface and a second surface, the first surface configured to face the flip chip device; a frame for securing the printed circuit board in place; a plurality of probe pins extending from the first surface in a manner which causes free ends of the pins to contact a plurality of bumps on the flip chip device; and a support member attached substantially flush with the frame above the second surface of the printed circuit board.

### BACKGROUND

The present invention relates generally to testing of integrated circuits using probe cards, and more particularly, to improved probe cards for flip chip testing.

Testing is a key enabling technology in the art of integrated circuit manufacturing. Typically, testing is performed at the wafer-level and at the package level. When a device is tested at the wafer level, coupling between the device under test (“DUT”) and the automated test system is made possible using a probe card. Referring to FIG. 1, a simplified, automated test system is shown. Automated test equipment (“ATE”) 10 conventionally includes a high speed and high precision testing circuit. The ATE 10 is coupled to a wafer prober station 14. The wafer prober station 14 contains a test head or probe head 18. Wafers are loaded under the test head where they are placed on a wafer stage for testing.

The automated test system is typically an expensive tool. It is therefore designed as a general-purpose tool to test a number of different integrated circuit designs. Flexibility of use is derived by storing a number of testing programs in ATE 10 that may be selected by the user interface 22 prior to each test. In addition, it is well-known that integrated circuit devices employ a variety of input/output (“I/O”), power and ground pins or terminals. Therefore, the test system must be able to account for these differences. Conventionally, this flexibility is derived by using probe cards.

A probe card is an interface card between the test head 18 and the DUT. The probe card translates the fixed pin-out capabilities, such as hard wired input channels or output channels of the ATE into an arrangement of pins custom interfaced to a specific IC design. Thus, ATE system 10 can be used to test a number of different designs using a common test head 18.

Referring to FIG. 2, a cross-sectional view of a probe card 30 attached to an integrated circuit under test and positioned on a wafer stage 50 is shown. In flip chip testing, the integrated circuit 38 is a flip chip device comprising a plurality of dies. Each of the plurality of dies has internal circuitry connected to raised solder bumps 42 on the surface of the die. Probe card 30 comprises a set of probe pins 34 that are aligned to physically touch each of the solder bumps 42 of the device under test. In this example, a single die is contacted by probe card 30 for testing. In practice, multiple dies can be probed at one time. Probe card 30 couples these probe pins 34 to interconnecting metal lines in the probe card structure that can connect to the test head of the ATE system when the probe card 30 is installed in the test head 18.

A typical probe card consists of a printed circuit board (PCB). When the probe pins are brought into contact with the solder bumps, the force on each pin is typically around 6 grams per 0.001 inch overdrive. As an example, assuming that there are 4000 pins on one probe card and 7 grams per 0.001 inch overdrive is applied to the wafer under test, the force of impact to the PCB of the probe card will be about 168 kg. A problem associated with conventional probe cards is that when the maximum overdrive is applied to bring the probe pins into contact with the solder bumps, the PCB will slightly deflect or bend under the large force applied to the solder bumps. FIG. 3 shows such a deflection of probe card 30 when the probe pins 34 engage the solder bumps (not shown). The bending of the PCB is at the area of the probe pins where the center pins are slightly depressed in contrast with the corner pins, where the force applied to the bumps by the corner pins are larger. When the PCB of the probe card deflects, the forces applied to the center and the corner solder bumps of the die will be different resulting in uneven solder bump height profiles. FIG. 4A shows a top view of the solder bumps 42 at the corner probe mark area of the die after probe testing and FIG. 4B shows a top view of the solder bumps 42 at the center probe mark area of the die after probe mark testing. In this example, from the top looking down, the corner solder bumps 42 show a slightly flatter or depressed height profile, or about 33% when compared to the center solder bumps at 17%, where there has been less damage thereto. The bump height profile variation is thus 16% (33%−17%=16%) between the bumps at the corners and the center of the die. These variations in bump height profile from the center to the corners of the die will cause device performance issues due to the uneven coplanarity of the plurality of solder bumps. When the flip chip is flipped over and attached directly to a system-level circuit, such as a circuit board or a ceramic substrate, the flatter profiled bumps at the corners of the die may not correctly make electrical contact with the substrate leading to device performance and reliability problems, which in turn reduces production yield.

For these reasons and other reasons that will become apparent upon reading the following detailed description, there is a need for an improved probe card for flip chip testing that avoids the problems associated with conventional probe cards.

### SUMMARY

The present invention is directed to a probe card for testing a flip chip device. In one embodiment, the probe card comprises a printed circuit board having a first surface and a second surface, the first surface configured to face the flip chip device; a frame for securing the printed circuit board in place; a plurality of probe pins extending from the first surface in a manner which causes free ends of the pins to contact a plurality of bumps on the flip chip device; and a support member attached substantially flush with the frame above the second surface of the printed circuit board.

### BRIEF DESCRIPTION OF THE DRAWINGS

The patent or application file contains at least one drawing executed in color. Copies of this patent

The features, aspects, and advantages of the present invention will become more fully apparent from the following detailed description, appended claims, and accompanying drawings in which:

FIG. 1 is a schematic illustration of an automated test system for testing integrated circuit devices.

FIG. 2 is a cross-sectional view of a probe card attached to an integrated circuit device under test.

FIG. 3 is a cross-sectional view of a probe card showing warpage of the probe card during testing when the probe pins engage the bumps of a device under test.

FIG. 4A is a top view of solder bumps at the corner probe mark area of the die following probe testing.

FIG. 4B is a top view of solder bumps at the center probe mark area of the die following probe testing.

FIG. 5 shows a support member mounted on a probe card to prevent probe card warpage during testing according to one aspect of the present invention.

FIG. 6A is a top view of solder bumps at the corner probe mark area of the die following probe testing according to one aspect of the present invention.

FIG. 6B is a top view of solder bumps at the center probe mark area of the die following probe testing according to one aspect of the present invention.

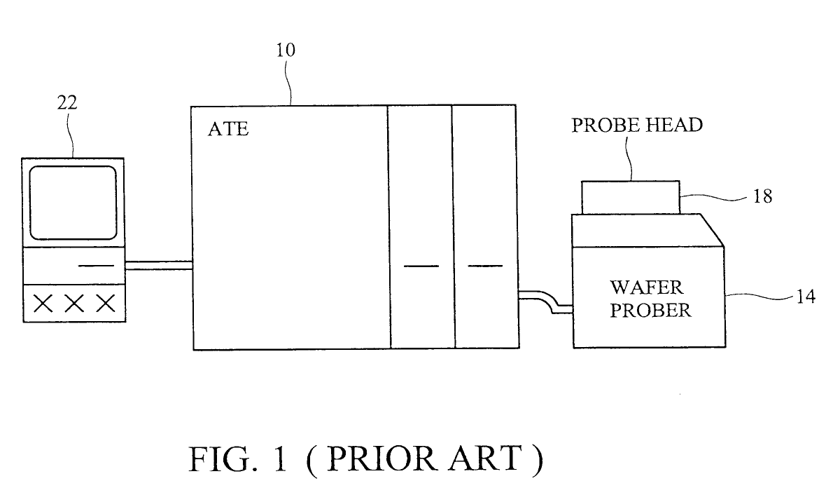

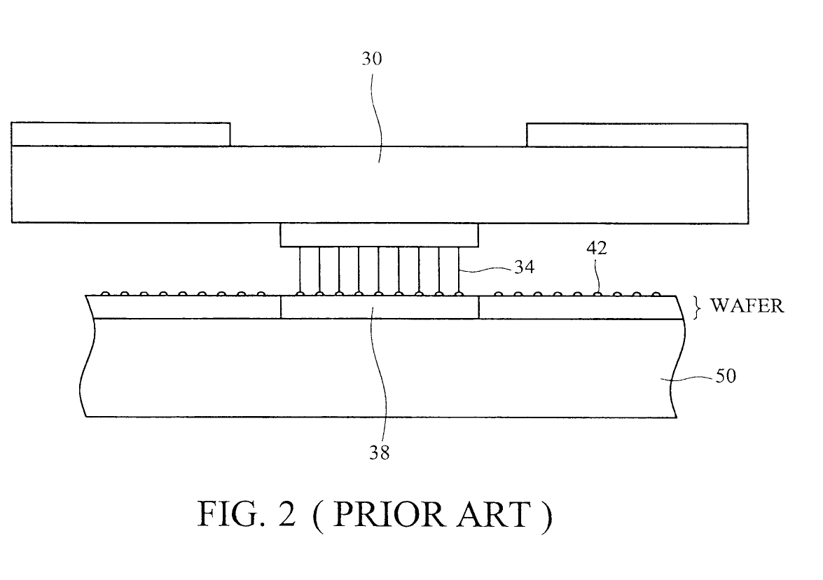

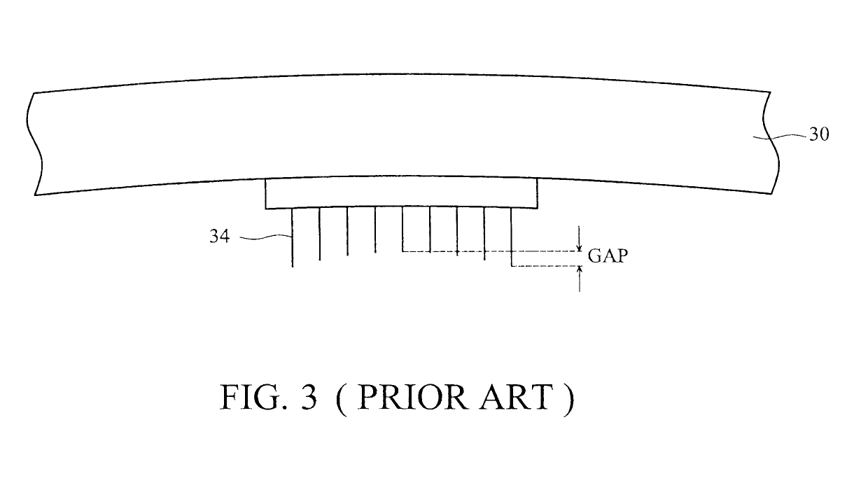

### DETAILED DESCRIPTION

In the following description, numerous specific details are set forth to provide a thorough understanding of the present invention. However, one having an ordinary skill in the art will recognize that the invention can be practiced without these specific details. In some instances, well-known structures and processes have not been described in detail to avoid unnecessarily obscuring the present invention.

Reference will now be made in detail to the present preferred embodiments of the present invention, examples of which are illustrated in the accompanying drawings.

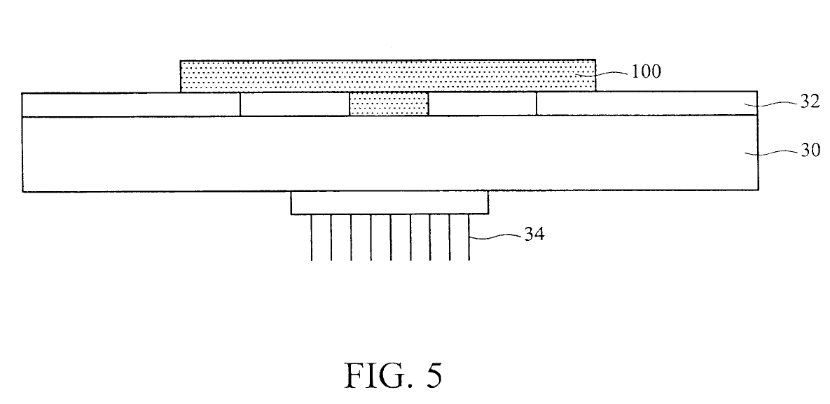

The present invention relates to an improved probe card for integrated circuit testing, particularly for flip chip testing. FIG. 5 is a side view of a probe card, denoted by numeral 30, according to an embodiment of the present invention. The probe card 30 comprises a planar board such as a printed circuit board (PCB) and a plurality of probe pins 34 extending from a bottom surface of probe card 30. Probe card 30 may be, for example a Cobra® vertical probe card to test the electrical operation of flip chip devices. Probe card 30 also includes a frame 32 for securing the printed circuit board in place. Probe pins 34 are aligned to physically contact each of the solder bumps of the flip chip device under test. The probe card 30 applies and receives electrical signals to and from raised solder bumps (not shown) via the probe pins 34 and the PCB, and may be connected to a testing apparatus (not shown) so that the test results can be recorded, analyzed, displayed, etc. The probe card 30 may be configured to apply electrical currents for adjusting the integrated circuit.

One aspect of the present invention is that the probe card 30 includes a support member 100 to prevent probe card bending during device testing. Support member 100 is installed on probe card 30 and configured to attach substantially flush with frame 32 above the upper surface of the printed circuit board. As shown in FIG. 5, support member 100 comprises a portion configured to be disposed within a recess formed in frame 32, the portion for abutting against the upper surface of the printed circuit board. In this way, support member 100 aids in reducing deflection of the printed circuit board, and consequently promoting planarity of the PCB, when probe pins 34 make contact with the solder bumps during flip chip device testing. Support member 100 also adds additional mechanical stability to the probe card 30.

Support member may be secured to frame 32 by way of one or more screws or by a layer of adhesive, such as epoxy. Epoxy is sturdy, electrically non-conductive, and able to withstand high temperatures. In one embodiment, support member 100 may be formed of any rigid material, such as metal, that substantially prevents deflection of the printed circuit board during testing. In another embodiment, support member 100 may comprise of any shape so long as it substantially prevents deflection of the printed circuit board during testing. In yet another embodiment, support member 100 may contain one or more elongations that extend substantially flush with frame 32 and extend over an area of the probe card overlapping probe pins 34. The elongations add additional mechanical stability to probe card 30. In yet another embodiment, support member 100 may contain one or more elongations that extend substantially flush with frame 32 and extend substantially over an entire area of the probe card. In another embodiment, support member has a plurality of holes drilled or formed therein to promote air convection during chip testing.

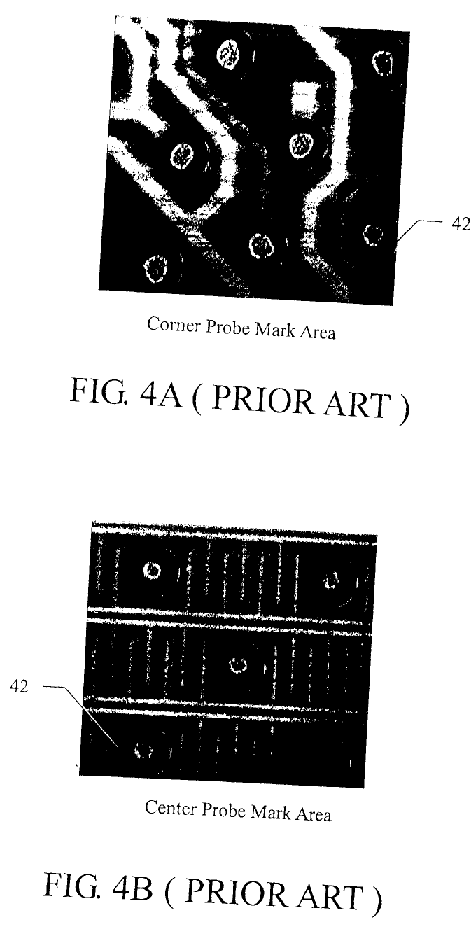

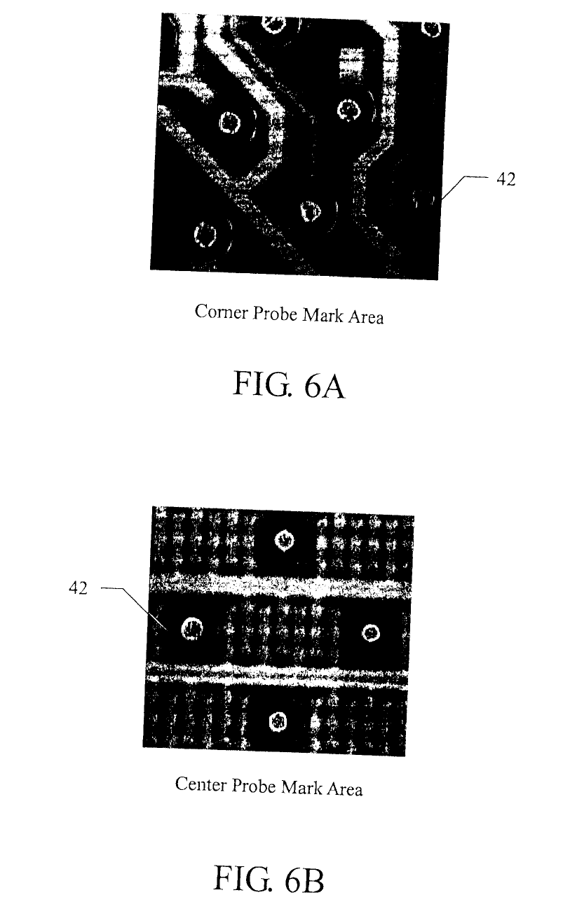

FIG. 6A shows a top view of solder bumps at the corner probe mark area of the die and FIG. 6B shows a top view of the solder bumps at the center probe mark area of the die following probe testing according to aspects of the present invention. In this example, from the top looking down, the corner solder bumps 42 show a slightly flatter or depressed height profile, or about 29% when compared to the center solder bumps at 21%. The bump height profile variation is thus 8% (29%-21%) between the bumps at the corners and center of the die. This bump height profile variation of 8% is less than the bump profile variation of 16% (see FIG. 4) for conventional probe cards used in flip chip testing. The result is that when the flip chip is flipped over for attachment to a system-level circuit board, the solder bumps having a more even height profile at the center as well as at the corners of the chip will make electrical contact with the system-level circuit board.

In the preceding detailed description, the present invention is described with reference to specifically exemplary embodiments thereof. It will, however, be evident that various modifications, structures, processes, and changes may be made thereto without departing from the broader spirit and scope of the present invention, as set forth in the claims. The specification and drawings are, accordingly, to be regarded as illustrative and not restrictive. It is understood that the present invention is capable of using various other combinations and environments and is capable of changes or modifications within the scope of the inventive concept as expressed herein.

What is claimed is:

1. A probe card for testing a flip chip device, the probe card comprising:
a printed circuit board having a first surface and a second surface, the first surface configured to face the flip chip device;
a frame for securing the printed circuit board in place;
a plurality of probe pins extending from the first surface in a manner which causes free ends of the pins to contact a plurality of bumps on the flip chip device; and
a support member attached substantially flush with the frame above the second surface of the printed circuit board.

2. The probe card of claim 1, wherein a portion of the support member is disposed within a recess formed in the frame and abuts against the second surface of the printed circuit board.

3. The probe card of claim 1, wherein the support member is attached to the frame by means of one or more screws.

4. The probe card of claim 1, wherein the support member has a plurality of holes therein.

5. The probe card of claim 1, wherein the support member extends substantially flush with the frame and overlaps the probe pins.

6. The probe card of claim 1, wherein the support member extends substantially flush with the frame, along the length of the probe card.

7. The probe card of claim 1, wherein the support member comprises a rigid material to substantially prevent deflection of the printed circuit board during testing.

8. The probe card of claim 7, wherein the rigid material comprises a metal.

9. The probe card of claim 1, wherein the support member comprises a shape that substantially prevents deflection of the printed circuit board during testing.

10. A test apparatus comprising:
a printed circuit board having a first surface and a second surface, the first surface configured to face a wafer containing a plurality of imaging die to be tested;
a frame for securing the printed circuit board in place;
a plurality of probe pins extending from the first surface in a manner which causes free ends of the pins to contact a plurality of bumps on an imaging die;
a support member attached substantially flush with the frame above the second surface of the printed circuit board; and
a microprocessor-based computer interconnected to circuitry on the printed circuit board for testing.

11. The test apparatus of claim 10, wherein a portion of the support member is disposed within a recess formed in the frame and abuts against the second surface of the printed circuit board.

12. The test apparatus of claim 10, wherein the support member is attached to the frame by means of one or more screws.

13. The test apparatus of claim 10, wherein the support member extends substantially flush with the frame and overlaps the probe pins.

14. The test apparatus of claim 10, wherein the support member extends substantially flush with the frame, along the length of the probe card.

15. A method of testing a wafer, comprising:
supporting the wafer containing a plurality of imaging die;
advancing a probe card onto an imaging die, the probe card having:
a printed circuit board having a first surface and a second surface, the first surface configured to face the imaging die;
a frame for securing the printed circuit board in place; and
a plurality of probe pins extending from the first surface in a manner which causes free ends of the pins to contact a plurality of bumps on the imaging die;
attaching a support member substantially flush with the frame above the second surface of the printed circuit board, the support member having a portion disposed within a recess formed in the frame and abutting against the second surface of the printed circuit board; and
testing the imaging die.

16. The method of claim 15, wherein the support member is attached to the frame by means of one or more screws.

17. The method of claim 5, wherein the support member extends substantially flush with the frame and overlaps the probe pins.

18. The method of claim 15, wherein the support member extends substantially flush with the frame, along the length of the probe card.

19. A method of manufacturing a probe card, comprising:
developing a printed circuit board having a first surface and a second surface, the first surface configured to face a device to be tested;
developing a frame for securing the printed circuit board in place;
developing a plurality of probe pins extending from the first surface in a manner which causes free ends of the pins to contact a plurality of bumps on the device; and
developing a support member for attaching substantially flush with the frame above the second surface of the printed circuit board, the support member having a portion disposed within a recess formed in the frame and abutting against the second surface of the printed circuit board.

20. The method of claim 19, wherein the support member is attached to the frame by means of one or more screws.
